(19) United States
(12) Patent Application Publication
(10) Pub. No.: US 2026/0079194 A1
(43) Pub. Date: Mar. 19, 2026

(54) METHOD FOR ASCERTAINING A FAULT LOCATION IN AN ELECTRICAL SUPPLY SYSTEM

(71) Applicant: Siemens Aktiengesellschaft, München (DE)

(72) Inventor: Jörg Blumschein, Berlin (DE)

(21) Appl. No.: 19/332,488

(22) Filed: Sep. 18, 2025

(30) Foreign Application Priority Data
Sep. 18, 2024 (EP) 24201061.9

(51) Int. Cl. G01R 31/11

(52) U.S. Cl. CPC G01R 31/11

(57) ABSTRACT

A method for ascertaining a fault location on a conductor in an electrical energy supply system. Electrical variables are recorded by sensors at first and second measuring points that are connected through a conductor with a total length L_{ab}. The sensors are connected to intelligent electronic devices IEDs. The measurement signals from the sensors are examined for the presence of a traveling wave. Upon determining that a traveling wave is present at both measuring points, a propagation time ratio factor F is calculated, indicating a propagation time of the traveling wave from the fault location to the first measuring point relative to a propagation time of the traveling wave from the first to the second measuring point. A distance X of the fault location from the first measuring point is calculated by multiplying the propagation time ratio factor F with the total length L_{ab}−X=F·L_{ab}.

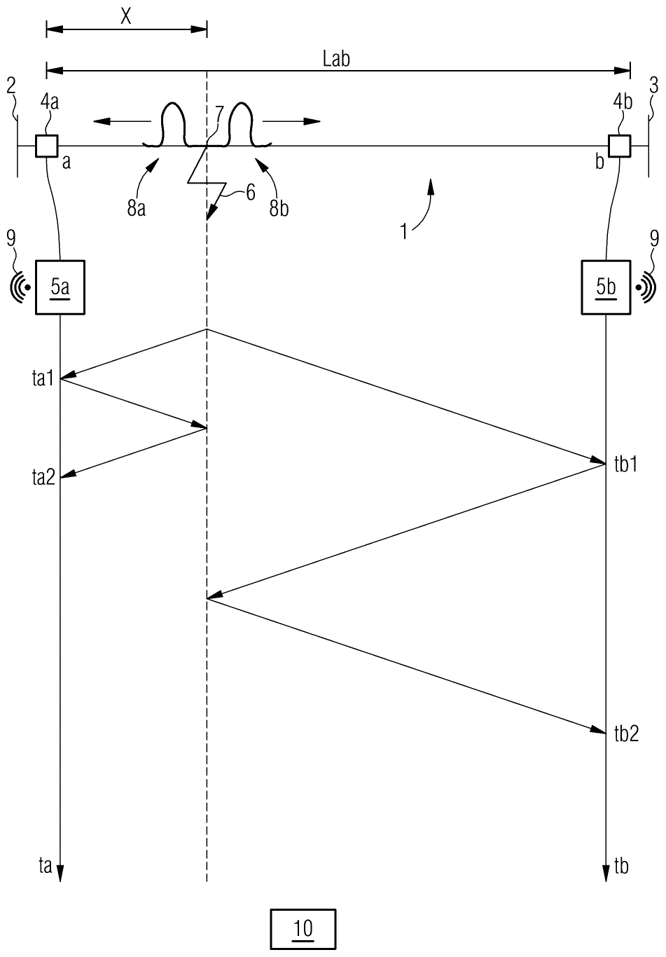

### CROSS-REFERENCE TO RELATED APPLICATION

This application claims the priority, under 35 U.S.C. § 119, of European Patent Application EP 24201061.9, filed Sep. 18, 2024; the prior application is herewith incorporated by reference in its entirety.

### FIELD AND BACKGROUND OF THE INVENTION

The invention relates to a method for ascertaining a fault location in an electrical energy supply system, in which a respective electrical measured variable is recorded at a first measuring point and a second measuring point in the energy supply system by means of a respective measuring sensor to obtain a first or a second measurement signal. Each measuring point is arranged in the immediate vicinity of a busbar or on a busbar and each measuring sensor is connected to a respective intelligent electronic device IED. The L_{ab} indicates a total length of the conductor section of the energy supply system between the first measuring point and the second measuring point or the busbars. The measurement signals of the first measuring point and the second measuring point are each examined for the presence of a traveling wave.

The reliable operation of electrical energy supply systems requires fast and reliable identification and shutdown of any faults, such as for example short circuits or ground faults. Causes of faults that bring about a shutdown may be for example lightning strikes, torn or otherwise damaged lines, faulty insulation in cable lines or unwanted contact between overhead lines and parts of animals or plants. In order to shorten fault-induced downtimes, such faults have to be located as accurately as possible in order to allow a maintenance team to rectify the cause of the fault, along with any resulting damage caused by the fault.

In the simplest, but also most expensive case, fault location takes place by manual inspection. A maintenance team then removes the faulty line and examines it for visible points of fault. It is also known practice to use drones that are equipped with cameras to fly over the faulty line. Their image data is transferred to a central station. These procedures, however, are time-consuming and susceptible to errors.

A different procedure has therefore largely been adopted, whereby the fault location at which the fault is located on the line is demarcated through the analysis of measured variables, for example currents and voltages, recorded during the occurrence of the fault. To this end, in the meantime, multiple different methods have become known, the accuracy of which has a significant effect on the maintenance expenditure of the energy supply system. Great value is therefore placed on improving the accuracy of the algorithms used for fault location, in order to facilitate maintenance and in particular to shorten fault-induced downtimes of the energy supply system.

It is known from European Patent EP 2476002 B1 that it is possible to narrow down the fault location by determining the fault direction. This method is mainly used in compensated, isolated and high-resistance grounded energy supply systems with a radial structure and a low degree of meshing. For example, a watt-metric method may be used.

Methods for more accurate fault location use the measured current or voltage signals of the fundamental wave (50 Hz or 60 Hz signals) for fault location. In this case, methods are known that use measured values from only one of the ends of the line (single-sided fault location) or measured values from both ends of the line (two-sided fault location). As a result, the fault location is generally given as the distance from the respective measuring point (in terms of percentage of the line or in kilometers or miles).

U.S. Pat. No. 4,996,624 describes a fault location method in which measured values from only one end of the line are used. The effort required here to carry out fault location is therefore low. That fault location method is predominantly an impedance-based method in which an impedance to the fault location is calculated from current and voltage measured values. It is possible to draw a conclusion with regard to the fault location through comparison with the line impedance of the entire line in the fault-free case.

U.S. Pat. No. 5,929,642 provides a fault location method that has a higher accuracy by virtue of using measured values from both ends of the line. In that case, the fault location-related measured values have to be combined via a suitable communication connection. A high degree of accuracy (measurement error of approximately 1-2%) in the fault location is achieved using estimation methods and non-linear optimization methods.

The method as summarized at the outset above is disclosed in U.S. Pat. No. 8,655,609 B2. A two-sided traveling wave fault location method is disclosed therein. While the accuracy of fault location in impedance-based fault location methods is dependent on the measurement accuracy of the transducers that are used and on the condition of the system, using a fault location method in accordance with what is known as the traveling wave principle (“traveling wave fault location”) makes it possible to achieve a large degree of independence from these variables. In accordance with this principle, instead of the fundamental waves of the measured current or voltage signals, the transient signal components occurring during the fault, which take the form of what are known as “traveling waves,” are taken into consideration for fault location. In that case, the high-frequency traveling wave edges are recorded using measurements and provided with a timestamp. Since the propagation speed of the traveling waves is roughly the speed of light, it is possible to achieve the localization of the fault from the evaluation of the timestamp. A disadvantage of that method is that the exact propagation speed of the traveling waves must be specified when calculating the fault location. However, this can fluctuate from system to system and may not always be ascertained accurately.

The infrastructure needed for the two-sided traveling wave fault location requires a communication connection between the measuring devices at the different measuring points, on the one hand, and exact time synchronization of the two measuring devices, on the other hand. Alternatively, in addition to the two measuring devices, a central evaluation unit, which has communication connections to both measuring devices, may be used in the field. For economic reasons, the associated device-related complexity currently limits the appeal of traveling wave fault location to comparatively expensive high voltage applications and extra-high voltage applications. Therefore, such fault location systems are preferably used in cases where the faulty line being available again more quickly justifies an expensive infrastructure.

Published International Application WO 2016/118584 A1 discloses a method for single-sided traveling wave fault location that is based on the comparison of traveling waves generated during a planned fault event with the traveling waves generated during a fault. However, for that purpose, complex comparative measurements are required for recording the traveling waves through measurement in the event of a planned fault event.

### SUMMARY OF THE INVENTION

The object of the invention is to provide a method of the type mentioned at the outset, that is to say fault location in accordance with the two-sided traveling wave principle, which is accurate and at the same time cost-effective.

With the above and other objects in view there is provided, in accordance with the invention, a method for ascertaining a fault location in an electrical energy supply system, the method comprising:
providing a first measuring sensor for measuring an electrical measured variable at a first measuring point, wherein the first measuring point is arranged in an immediate vicinity of, or on, a first busbar of the electrical energy supply system, and the first measuring sensor is connected to an intelligent electronic device IED;
providing a second measuring sensor for measuring an electrical measured variable at a second measuring point, wherein the second measuring point is arranged in an immediate vicinity of, or on, a second busbar of the electrical energy supply system, and the second measuring sensor is connected to an intelligent electronic device IED;
a) recording a respective electrical measured variable at the first measuring point and at the second measuring point by a respective measuring sensor to obtain a first measurement signal and a second measurement signal, respectively;
wherein a conductor of the energy supply system extends between the busbars and L_{ab} indicates a total length of a conductor section between the first measuring point and the second measuring point or between the busbars;
b) examining the measurement signals of the first measuring point and the second measuring point for a presence of a traveling wave;
c) after determining the presence of the traveling wave at both the first and second measuring points aided by a chronologically first reflection of the traveling wave at the respective busbar and then at the fault location, calculating a propagation time ratio factor F, which indicates a propagation time of the traveling wave from the fault location to the first measuring point relative to a propagation time of the traveling wave from the first measuring point to the second measuring point; and
d) calculating a distance X of the fault location from the first measuring point by forming a product of the propagation time ratio factor F and the total length L_{ab} in accordance with

$$X = F \cdot {L}_{a b} .$$

In other words, the objects of the invention are achieved by virtue of the fact that, after determining the presence of a traveling wave at both measuring points with the aid of the first reflection of said traveling wave at the respective busbar and at the fault location, a propagation time ratio factor F is calculated, which indicates the propagation time of the traveling wave from the fault location to the first measuring point in relation to the propagation time of said traveling wave from the first measuring point to the second measuring point, and by virtue of the fact that the distance X of the fault location from the first measuring point is calculated from the product of the propagation time ratio factor F and the total length L_{ab} in accordance with

$$X = F \cdot {L}_{a b} .$$

Within the context of the invention, two-sided traveling wave fault location is provided, which does not require high-precision time synchronization between the measuring points. This considerably reduces device-related complexity. In addition, within the context of the invention, the propagation speed of the traveling wave is no longer included in the ascertainment of the fault location. Within the context of the invention, inaccuracies resulting from this are consequently avoided. In addition, error factors arising from the different lengths of the signal lines between the measuring sensors and their connection device are also not relevant within the context of the invention.

The method according to the invention is based on previously known methods of single-sided traveling wave fault location. Within the context of the invention, the occurrence of a traveling wave and the reflection thereof at the fault location is recorded at both measuring points independently of one another. The high-frequency edges of the traveling wave or the reflection of the traveling wave are recorded using measurements and provided with a timestamp. Reflections of the traveling wave occurring in the event of a fault first take place at the location of the measuring point or, more specifically, at the busbar that is also arranged there. The traveling wave reflected by the busbar travels back to the fault location and is also reflected there and travels back to the measuring point, where the edge of this first reflection is recorded using measurements and provided with a second timestamp. The arrival of the traveling wave triggered by the fault in the energy supply system and the first reflection thereof, which has just been described, is able to be detected at both measuring points. Within the context of the invention, the time periods between the recording of the traveling wave and the first reflection thereof at both measuring points are taken into account.

Within the context of the invention, the expression “arranged in the immediate vicinity of a busbar” is intended to mean that the measuring point is arranged on the line side of the busbar and specifically at a distance of 0.01 to 100 meters from the busbar. The term “busbar” is intended to represent all components at which a traveling wave is able to be reflected. Within the context of the invention, the measuring point may also be arranged on the busbar itself. In other words, the measurement is performed on the busbar. In the case of said small distances (0.01 to 100 meters) between the measuring point and the busbar, when ascertaining the fault location, it may be assumed to good approximation that the reflection practically takes place at the measuring points. However, in the case of greater distances between the measuring points and the respective busbar, the distance between the measuring point and the respective busbar has to be taken into account in the fault location.

The conductor section between the first measuring point and the second measuring point is advantageously in the form of a mesh-free and node-free conductor. In other words, according to this further development of the invention, a linear conductor is monitored. This simplifies the recording of the traveling waves using measurements. In particular, identifying the first reflection of the traveling wave at the fault location is simplified in comparison to other disturbing reflections.

Preferably, the propagation time ratio factor F is formed exclusively from a time difference Δtₐ that is recorded at the first measuring point and a time difference Δt_{b} that is recorded at the second measuring point. A comparison of the timestamps of one measuring point with a timestamp of the second measuring point is thereby avoided.

According to a further development of the invention in this regard, the times tₐ₁ and tₐ₂ are recorded at the first measuring point and Δtₐ is calculated in accordance with

$$Δ {t}_{a} = \frac{1}{2} ( {t}_{a 2} - {t}_{a 1} ) ,$$

wherein tₐ₁ indicates the time at which the traveling wave arrives and tₐ₂ indicates the time at which the first reflection of said traveling wave arrives at the first measuring point. At the same time, the times t_{b1} and t_{b2} are recorded at the second measuring point, wherein Δt_{b} is calculated in accordance with

$$Δ {t}_{b} = \frac{1}{2} ( {t}_{b 2} - {t}_{b 1} ) ,$$

wherein t_{b1} indicates the time at which the traveling wave arrives and t_{b2} indicates the time at which the reflection of the traveling wave arrives at the second measuring point. In this case too, the arriving traveling wave is initially reflected at the busbar, that is to say practically at the measuring point, and then at the fault location. In principle, a traveling wave is reflected arbitrarily often between the fault location and the busbar. The amplitude of the wave decreases steadily, but the propagation time from the fault location to the busbar remains the same. However, the first reflection may be detected with sufficient accuracy. If a plurality of reflections from the fault location are able to be measured, these may be used within the context of the invention to verify the time differences Δtₐ and Δt_{b} ascertained from the first reflection. This must first be ensured. It is also expedient to validate the measurements if the propagation time over the entire line that is calculated from the sum of Δtₐ and Δt_{b} is compared with a predetermined “target value” for the propagation time over the line. In addition, it is possible to check the fault location according to the invention using two-sided fault location with high-precision time synchronization.

According to a preferred variant of the method according to the invention, the propagation time ratio factor F is calculated with reference to the time differences Δtₐ and Δt_{b} in accordance with

$$F = \frac{Δ {t}_{a}}{Δ {t}_{a} + Δ {t}_{b}} .$$

According to a further development of the invention, the propagation time of the traveling wave from the fault location to the first measuring point is ascertained from the difference between the time tₐ₂ at which the first reflection of the traveling wave arrives at the first measuring point and the time tₐ₁ at which the traveling wave arrives at the first measuring point in accordance with

$$Δ {t}_{a} = \frac{1}{2} ( {t}_{a 2} - {t}_{a 1} ) .$$

According to this further development in this regard, the propagation time of said traveling wave from the first measuring point to the second measuring point t_{ab} is calculated from the sum of the propagation time of the traveling wave from the fault location to the first measuring point Δtₐ and the propagation time of the traveling wave from the fault location to the second measuring point Δt_{b} in accordance with t_{ab}=Δtₐ+Δt_{b}, wherein

$$Δ {t}_{b} = \frac{1}{2} ( {t}_{b 2} - {t}_{b 1} ) ,$$

and wherein t_{b2} Indicates the time at which the reflection of the traveling wave arrives at the second measuring point and t_{b1} indicates the time at which the traveling wave arrives at the second measuring point.

Advantageously, within the context of the invention, two IEDs are provided, which are connected to a control center arrangement via a communication connection, wherein the control center arrangement localizes the fault location.

Deviating from this, the IEDs are connected to one another via a communication connection, with the result that the measured values are able to be transmitted between the IEDs. The fault location may then be calculated by one of the IEDs.

Control center arrangements are individual data processing apparatuses or groups of data processors that are arranged centrally or in a decentralized manner and usually execute complex algorithms for observing and/or controlling the installation. Control centers usually have a man-machine interface that makes it possible for an operator of the installation to observe and monitor the state of the installation as a whole and to observe and monitor the state of the individual components of the installation and to control individual or a plurality of components.

Within the context of the invention, the control center arrangement may also be implemented by a data processing cloud. A data processing cloud is intended to be understood here to mean an arrangement having one or more data storage apparatuses and one or more data processing apparatuses, which may be designed to carry out any desired data processing processes by means of suitable programming. In this case, the data processing apparatuses are generally universal data processing apparatuses (for example servers) that initially do not have any specific design whatsoever in terms of their construction and their programming. The universal data processing apparatus may be upgraded to perform specific functions only by means of programming that is carried out. If the data processing cloud has a plurality of individual components, these are connected to one another in a suitable manner for data communication (for example by means of a communication network). Any desired data may be supplied to a data processing cloud for data storage and/or processing. The data processing cloud itself in turn provides other devices, for example a computer workstation connected to the data processing cloud, with the stored data and/or the results of the data processing that has been carried out. Within the context of the invention, the term control center arrangement used here is also intended to extend to such a data processing cloud. A data processing cloud may also be provided, for example, by a computing center or a plurality of networked computing centers. A data processing cloud is usually spatially remote from the installation.

Intelligent electronic devices (IEDs) are able to independently perform tasks for automating or for protecting an electrical energy supply system while executing particular algorithms. In this context, IEDs may be, in particular, protective and control devices, measuring devices, power quality devices or power meters.

Within the context of the invention, a communication connection is understood to mean both wired connecting lines and wireless radio connections.

Other features which are considered as characteristic for the invention are set forth in the appended claims.

Although the invention is illustrated and described herein as embodied in a method for ascertaining a fault location in an electrical supply system, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawing.

### BRIEF DESCRIPTION OF THE FIGURE

The single FIGURE schematically shows an exemplary embodiment of the method according to the invention.

### DETAILED DESCRIPTION OF THE INVENTION

The sole FIGURE of the drawing shows an exemplary embodiment of the method according to the invention. In the example, the electrical energy supply system is a linear mesh-free and node-free line 1, which has a three-phase design. In other words, the line 1 comprises three individual phase conductors. The three conductors are not illustrated as such, for simplification of the FIGURE. The line, i.e., the conductor 1, extends from a first busbar 2 to a second busbar 3. Furthermore, two measuring points a and b may be seen, wherein the measuring point a is arranged in the immediate vicinity of the busbar 2 and the measuring point b is arranged in the immediate vicinity of the busbar 3. In the illustrated exemplary embodiment, the distance between the respective measuring point and the busbar is five meters. The measuring sensor 4a is located at the measuring point a, and the measuring sensor 4b is located at the measuring point b. Both measuring sensors are in the form of voltage transformers. Within the context of the invention, however, current transformers or small-signal transformers, for example, a Rogowski coil, may also be used.

Each measuring sensor 4a, 4b is connected to the measuring device input of an intelligent electronic device (IED) 5a or 5b. In the illustrated exemplary embodiment, the IEDs 5a, 5b are protective devices.

The measurement signals generated on the output side by the measuring sensors are supplied to the protective devices 5a or 5b. Each protective device 5a and 5b samples the analog measurement signals to obtain sample values, wherein the sample values are then digitized by an analog-to-digital converter to obtain measured values.

The FIGURE also indicates that there is a short circuit at a fault location 7 in the line 1. The short circuit itself is indicated by a jagged arrow 6. Traveling waves 8a and 8b occur at the fault location 7 due to the short circuit, wherein the traveling wave 8a travels from the fault location 7 to the measuring point a and the traveling wave 8b travels from the fault location 7 to the measuring point b. The traveling waves 8a and 8b are so-called transient signal components, which have a high frequency.

Below the line 1 and the protective devices 5a, 5b, two timelines ta and tb may be seen in the FIGURE that are intended to indicate the time recording of the respective protective device 5a and 5b. The protective devices 5a and 5b have an internal clock or timing unit for measuring time, with the aid of which a timestamp can be generated. The clocks of the protective devices 5a and 5b are not synchronized with one another. In the FIGURE, the time recording of the clock of the protective device 5a is indicated by the timeline ta and the time recording of the clock of the protective device 5b is indicated by the timeline tb.

When the traveling wave 8a arrives at the measuring point a, its high-frequency edge is provided with the timestamp tₐ₁. In other words, the time tₐ₁ indicates the arrival of the traveling wave 8a at the measuring point a. This is shown schematically with an arrow, the tip of which touches the timeline at tₐ₁. The reflection of the traveling wave at the busbar 2 provides another arrow, the tip of which is on the dashed line that runs parallel to the timelines ta and tb and is arranged between them in the FIGURE. At the fault location 7, which is symbolized by the dashed line in the FIGURE, a renewed reflection of the traveling wave 8a occurs, which may then be detected again at the measuring point a as the first reflection. The time at which the first reflection of the traveling wave is recorded at the measuring point a is indicated by tₐ₂ on the timeline ta.

On the other side of the line 1, on side b, a corresponding procedure is followed. The arrival of the traveling wave 8b at the measuring point b is provided with the timestamp t_{b1}. The traveling wave 8b is then reflected at the busbar 3 again in the direction of the fault location 7 with a renewed reflection at the fault location 7 as a result. The arrival of the traveling wave, which is reflected at the fault location 7, at the measuring point b is provided with the timestamp t_{b2}.

The protective devices 5a and 5b are each connected to a control center arrangement 10 via a communication connection 9, with the aid of which the above-mentioned timestamps of the traveling waves 8a and 8b and the first reflections thereof are transmitted to the control center arrangement 10. In the exemplary embodiment shown, the communication connection 9 is a wireless radio connection. The control center arrangement 10 is now able to locate the short circuit, that is to say determine or narrow down the distance of the fault location from the measuring point a.

In order to ascertain the fault location 7, i.e. the distance X of the fault location 7 from the measuring point a, a propagation time ratio factor F is calculated within the context of the invention by the control center 10. This factor F corresponds to the ratio of the propagation time of the traveling wave 8a from the fault location 7 to the measuring point a in relation to the propagation time of a corresponding traveling wave over the entire length of the line 1 from the measuring point a to the measuring point b. This distance is referred to below as Lab.

According to the invention, the propagation time of the traveling wave 8a from the fault location 7 to the first measuring point a is ascertained from the difference between the time tₐ₂ at which the first reflection of the traveling wave arrives and the time taj at which the traveling wave arrives at the first measuring point in each case in accordance with

$$Δ {t}_{a} = \frac{1}{2} ( {t}_{a 2} - {t}_{a 1} ) .$$

The propagation time of a corresponding traveling wave from the first measuring point a to the second measuring point b, which is indicated by t_{ab}, may be calculated from the sum of the propagation time of the traveling wave 8a from the fault location 7 to the first measuring point a, which is indicated by Δtₐ, and the propagation time of the traveling wave 8b from the fault location 7 to the second measuring point b (Δt_{b}) in accordance with t_{ab}=(Δtₐ+Δt_{b}), wherein

$$Δ {t}_{b} = \frac{1}{2} ( {t}_{b 2} - {t}_{b 1} )$$

is calculated. The propagation time ratio factor F may therefore be calculated in accordance with

$$F = \frac{Δ {t}_{a}}{Δ {t}_{a} + Δ {t}_{b}}$$

and the distance X from the measuring point a results in accordance with

$$X = F \cdot {L}_{ab} = \frac{Δ {t}_{a}}{Δ {t}_{a} + Δ {t}_{b}} {L}_{ab} .$$

1. A method for ascertaining a fault location in an electrical energy supply system, the method comprising:
providing a first measuring sensor for measuring an electrical measured variable at a first measuring point, wherein the first measuring point is arranged in an immediate vicinity of, or on, a first busbar of the electrical energy supply system, and the first measuring sensor is connected to an intelligent electronic device IED;
providing a second measuring sensor for measuring an electrical measured variable at a second measuring point, wherein the second measuring point is arranged in an immediate vicinity of, or on, a second busbar of the electrical energy supply system, and the second measuring sensor is connected to an intelligent electronic device IED;
a) recording a respective electrical measured variable at the first measuring point and at the second measuring point by a respective measuring sensor to obtain a first measurement signal and a second measurement signal, respectively;
wherein a conductor of the energy supply system extends between the busbars and L_{ab} indicates a total length of a conductor section between the first measuring point and the second measuring point or between the busbars;
b) examining the measurement signals of the first measuring point and the second measuring point for a presence of a traveling wave;
c) after determining the presence of the traveling wave at both the first and second measuring points aided by a chronologically first reflection of the traveling wave at the respective busbar and then at the fault location, calculating a propagation time ratio factor F, which indicates a propagation time of the traveling wave from the fault location to the first measuring point relative to a propagation time of the traveling wave from the first measuring point to the second measuring point; and
d) calculating a distance X of the fault location from the first measuring point by forming a product of the propagation time ratio factor F and the total length L_{ab} in accordance with
$$X = F \cdot {L}_{ab} ;$$
and
e) outputting the distance X to indicate the location of the fault in the conductor between the busbars of the energy supply system.

2. The method according to claim 1, which comprises forming the propagation time ratio factor F exclusively from a time difference Δtₐ that is recorded at the first measuring point and a time difference Δt_{b} that is recorded at the second measuring point.

3. The method according to claim 2, which comprises:
recording times tₐ₁ and tₐ₂ at the first measuring point and calculating Δtₐ in accordance with
$$Δ {t}_{a} = \frac{1}{2} ( {t}_{a 2} - {t}_{a 1} ) ,$$
wherein tₐ₁ indicates a time at which the traveling wave arrives and tₐ₂ indicates a time at which the first reflection of said traveling wave arrives; and
recording times t_{b1} and t_{b2} at the second measuring point and calculating Δt_{b} in accordance with
$$Δ {t}_{b} = \frac{1}{2} ( {t}_{b 2} - {t}_{b 1} ) ,$$
wherein t_{b1} Indicates a time at which the traveling wave arrives and t_{b2} indicates a time at which the first reflection of the traveling wave arrives at the second measuring point.

4. The method according to claim 3, which comprises calculating the propagation time ratio factor F in accordance with
$$F = \frac{Δ {t}_{a}}{Δ {t}_{a} + Δ {t}_{b}} .$$

5. The method according to claim 3, which comprises ascertaining a propagation time of the traveling wave from the fault location to the first measuring point from the difference between the time tₐ₂ at which the first reflection of the traveling wave arrives and the time tₐ₁ at which the traveling wave arrives at the first measuring point in accordance with
$$Δ {t}_{a} = \frac{1}{2} ( {t}_{a 2} - {t}_{a 1} ) .$$

6. The method according to claim 5, which comprises:
calculating the propagation time t_{ab} of the traveling wave from the first measuring point to the second measuring point from a sum of the propagation time Δtₐ of the traveling wave from the fault location to the first measuring point and the propagation time Δt_{b} of the traveling wave from the fault location to the second measuring point in accordance with t_{ab}=(Δtₐ+Δt_{b});
wherein:
$$Δ {t}_{b} = \frac{1}{2} ( {t}_{b 2} - {t}_{b 1} ) ;$$
t_{b2} indicates the time at which the first reflection of the traveling wave arrives at the second measuring point; and
t_{b1} indicates the time at which the traveling wave arrives at the second measuring point.

7. The method according to claim 1, wherein the IED connected to the first measuring sensor and the IED connected to the second measuring sensor s are connected to a control center via a communication connection, and the control center is configured to localize the fault location.

8. The method according to claim 7, wherein each IED has a clock and the clocks are not synchronized with one another.
